(19) United States
(12) Patent Application Publication
(10) Pub. No.: US 2022/0208584 A1
(43) Pub. Date: Jun. 30, 2022

(54) WAFER TRANSFER METHOD AND MECHANICAL ARM

(71) Applicant: Piotech Inc., Shenyang (CN)

(72) Inventors: Jason Tian, Shenyang (CN); Zhuo Wang, Shenyang (CN); Hui Li, Shenyang (CN)

(21) Appl. No.: 17/555,631

(22) Filed: Dec. 20, 2021

(30) Foreign Application Priority Data
Dec. 31, 2020 (CN) 202011643091.2

(51) Int. Cl. H01L 21/677; H01L 21/687

(52) U.S. Cl. CPC H01L 21/67742; H01L 21/68764

(57) ABSTRACT

This application relates to a wafer transfer method and a mechanical arm. The method includes: providing a first wafer to a finger portion front end of a mechanical arm; extending the mechanical arm to a first length to move the finger portion front end of the mechanical arm to a first processing position in a first processing chamber; placing the first wafer at the first processing position; contracting the mechanical arm to move the finger portion front end of the mechanical arm out of the first processing chamber; providing a second wafer to the finger portion front end of the mechanical arm; extending the mechanical arm to a second length to move the finger portion front end of the mechanical arm to a second processing position in the first processing chamber, wherein the second length is different from the first length; and placing the second wafer at the second processing position.

### CROSS-REFERENCE TO RELATED APPLICATIONS

This application claims priority to Chinese Patent Application No. 202011643091.2 filed on Dec. 31, 2020, and all the benefits accruing therefrom under 35 U.S.C. § 119, the contents of which in its entirety are herein incorporated by reference.

### BACKGROUND OF THE INVENTION

### 1. Field of the Invention

This application generally relates to the field of semiconductor manufacturing, and more specifically, to a wafer transfer method and a mechanical arm for a semiconductor processing system.

### 2. Description of the Related Art

A processing chamber of a semiconductor processing system may include one or more processing stations, and each processing station may be used for processing one wafer. When transferring to-be-processed wafers to a processing chamber that includes a plurality of processing stations, usually a group of one or more wafers are first transferred to a position relatively closer to a valve of the processing chamber, and then the wafers are transferred, by using a rotation mechanism, to a position relatively farther from the valve of the processing chamber. Then a next group of one or more wafers are transferred to the position relatively closer to the valve of the processing chamber, and then the wafers are rotated. The steps are repeated until wafers are placed in all of the processing stations in the processing chamber. Implementation of such a transfer method needs to dispose a rotation mechanism in the processing chamber, which makes a device structure and operating procedures relatively complex, and may cause damage or contamination to a wafer during the rotation.

Therefore, there is a need for a simpler and more convenient wafer transfer method that can avoid rotation in the processing chamber and a mechanical arm applicable to implementation of such a method.

### SUMMARY OF THE INVENTION

This application provides at least a novel wafer transfer method and a mechanical arm applicable to such a method, which can avoid a rotation mechanism in a processing chamber.

In an implementation of this application, a wafer transfer method is provided. The method may include: providing a first wafer to a finger portion front end of a mechanical arm; extending the mechanical arm to a first length to move the finger portion front end of the mechanical arm to a first processing position in a first processing chamber; placing the first wafer at the first processing position; contracting the mechanical arm to move the finger portion front end of the mechanical arm out of the first processing chamber; providing a second wafer to the finger portion front end of the mechanical arm; extending the mechanical arm to a second length to move the finger portion front end of the mechanical arm to a second processing position in the first processing chamber, wherein the second length is different from the first length; and placing the second wafer at the second processing position.

In some embodiments, the method may include moving a base of the mechanical arm to the vicinity of the first processing chamber before extending the mechanical arm to the first length.

In some embodiments, the method may further include: providing a third wafer to the finger portion front end of the mechanical arm; extending the mechanical arm to a third length to move the finger portion front end of the mechanical arm to a third processing position in a second processing chamber; and placing the third wafer at the third processing position. In some embodiments, the method may include moving a base of the mechanical arm to the vicinity of the second processing chamber before extending the mechanical arm to the third length.

In some embodiments, the method may further include moving the first wafer and the second wafer out of the first processing chamber after treatment processes of the first wafer and the second wafer are completed. Moving the first wafer out of the first processing chamber may include: extending the mechanical arm to the first length to move the finger portion front end of the mechanical arm to the first processing position; moving the first wafer from the first processing position to the finger portion front end of the mechanical arm; contracting the mechanical arm to move the first wafer out of the first processing chamber; and removing the first wafer from the finger portion front end of the mechanical arm. Moving the second wafer out of the first processing chamber may include: extending the mechanical arm to the second length to move the finger portion front end of the mechanical arm to the second processing position; moving the second wafer from the second processing position to the finger portion front end of the mechanical arm; contracting the mechanical arm to move the second wafer out of the first processing chamber; and removing the second wafer from the finger portion front end of the mechanical arm.

In some embodiments, the first wafer is placed at the first processing position before the second wafer is placed at the second processing position, and the second wafer is moved out of the first processing chamber before the first wafer is moved out of the first processing chamber.

In some embodiments, providing the first wafer to the finger portion front end of the mechanical arm may include moving the first wafer from a first-layer load lock chamber to the finger portion front end of the mechanical arm, and removing the first wafer from the finger portion front end of the mechanical arm may include moving the first wafer from the finger portion front end of the mechanical arm to a second-layer load lock chamber.

In some embodiments, the finger portion front end of the mechanical arm is a first-layer finger portion front end of the mechanical arm. The method may further include: extending, after a treatment process of the first wafer is completed, the mechanical arm to move a second-layer finger portion front end of the mechanical arm to the first processing position; moving the first wafer from the first processing position to the second-layer finger portion front end of the mechanical arm; contracting the mechanical arm to move the first wafer out of the first processing chamber; and removing the first wafer from the second-layer finger portion front end of the mechanical arm.

In some embodiments, providing the first wafer to the finger portion front end of the mechanical arm may include moving the first wafer from a first-layer load lock chamber to the first-layer finger portion front end of the mechanical arm, and removing the first wafer from the second-layer finger portion front end of the mechanical arm may include moving the first wafer from the second-layer finger portion front end of the mechanical arm to a second-layer load lock chamber.

In some embodiments, the method may include: after contracting the mechanical arm to move the first wafer out of the first processing chamber and before removing the first wafer from the second-layer finger portion front end of the mechanical arm, extending the mechanical arm to move the first-layer finger portion front end of the mechanical arm to the first processing position, and placing a third wafer on the first-layer finger portion front end at the first processing position.

In another implementation of this application, a wafer transfer method is provided. The method may include: providing a first wafer to a first-layer finger portion front end of a mechanical arm; and performing the following operations during a single opening stage of a valve of a first processing chamber: extending the mechanical arm to move a second-layer finger portion front end of the mechanical arm to a first processing position in the first processing chamber; moving a second wafer in the first processing position to the second-layer finger portion front end of the mechanical arm; contracting the mechanical arm to move the second wafer out of the first processing chamber; extending the mechanical arm to move the first-layer finger portion front end of the mechanical arm to a second processing position in the first processing chamber; placing the first wafer at the second processing position; and contracting the mechanical arm to move the first-layer finger portion front end of the mechanical arm out of the first processing chamber.

In some embodiments, the first processing position and the second processing position may be the same processing position.

In another implementation of this application, a mechanical arm is provided. The mechanical arm may include: a first-layer extension unit mounted on a base, including a first small arm portion, a second small arm portion, a first big arm portion, and a second big arm portion, wherein a first end of the first small arm portion and a first end of the second small arm portion are connected at a first joint, a second end of the first small arm portion and a first end of the first big arm portion are connected at a second joint, a second end of the second small arm portion and a first end of the second big arm portion are connected at a third joint, and a second end of the first big arm portion and a second end of the second big arm portion are jointly connected to a supporting point on the base; and a first-layer finger portion, mounted on the first joint of the first-layer extension unit.

In some embodiments, the first big arm portion and the second big arm portion are thicker than the first small arm portion and the second small arm portion. In some embodiments, the second end of the first big arm portion and the second end of the second big arm portion are thicker than the first end of the first big arm portion and the first end of the second big arm portion. In some embodiments, the second end of the first small arm portion and the second end of the second small arm portion are thicker than the first end of the first small arm portion and the first end of the second small arm portion.

In some embodiments, the first small arm portion and the second small arm portion are operable to rotate around the first joint, the first small arm portion and the first big arm portion are operable to rotate around the second joint, the second small arm portion and the second big arm portion are operable to rotate around the third joint, and the first big arm portion and the second big arm portion are operable to rotate around the supporting point.

In some embodiments, the first-layer finger portion may include: a front end for carrying a wafer; and a rear end, connected between the front end and the first joint.

In some embodiments, the front end may include a hollow part. In some embodiments, the front end may include a plurality of contact points, a plurality of contact lines, or a plurality of contact bevels for supporting the wafer from a side of the wafer. In some embodiments, the front end may include a suction cup for sucking the wafer from the back of the wafer.

The suction cup may include an electrostatic suction cup or a vacuum suction cup.

In some embodiments, the first-layer finger portion may further include: a second-layer extension unit mounted on the base; and a second-layer finger portion mounted on the second-layer extension unit. In some embodiments, the first-layer extension unit and the second-layer extension unit are operable to extend independently of each other.

Details of one or more examples of this application are explained in the following accompanying drawings and descriptions. Other features, objectives and advantages will be obvious according to the descriptions, the accompanying drawings, and the claims.

### BRIEF DESCRIPTION OF THE DRAWINGS

The disclosure in this specification mentions and includes the following drawings:

FIG. 1 is a schematic structural diagram of a processing chamber including a plurality of processing stations according to some embodiments of this application.

FIG. 2 is a schematic structural diagram of a semiconductor processing system according to some embodiments of this application.

FIG. 3 is a schematic structural diagram of a mechanical arm according to some embodiments of this application.

FIG. 4 is a schematic structural diagram of another mechanical arm according to some embodiments of this application.

According to convention, various features illustrated in the drawings may not be drawn to scale. Therefore, the sizes of the various features may be increased or reduced arbitrarily for the purpose of clear description. The shape of each component illustrated in the drawings is only an exemplary shape, and does not limit the actual shape of the component. In addition, the implementations illustrated in the drawings may be simplified for clarity. Therefore, the drawings may not illustrate all components of a given device or apparatus. Finally, the same reference numerals may be used throughout the specification and the drawings to represent the same features.

### PREFERRED EMBODIMENT OF THE PRESENT INVENTION

The present disclosure is described below more completely with reference to the drawings, and particular exemplary embodiments are shown by using examples. However, the claimed subject matter may be specifically implemented in various different forms. Therefore, construction of the claimed subject matter covered or applied for is not limited to any exemplary embodiment disclosed in this specification; and the exemplary embodiments are only examples. Similarly, the present disclosure provides a properly broad scope for the claimed subject matter applied for or covered.

A phrase “in an embodiment” or “according to an embodiment” used in this specification does not necessarily refer to the same specific embodiment, and does not mean that the technical solution claimed to be protected has to include all features described in the embodiments. A phrase “in other (some/certain) embodiments” or “according to other (some/certain) embodiments” used in this specification does not necessarily refer to different specific embodiments. The purpose is, for example, that the claimed subject matter includes a combination of all or some exemplary embodiments. Terms “include” and “comprise” in this specification are used in an open manner, and therefore should be construed as “including, but not limited to . . . ”. The meanings of “upper” and “lower” in this specification are not limited to a relationship directly presented by the drawings, and should include description with a clear correspondence, such as “left” and “right”, or the opposite of “upper” and “lower”. A term “wafer” in this specification should be understood as being interchangeable with a term such as “substrate”, “chip”, or “silicon wafer”. This specification uses certain terms to refer to specific system components. As understood by a person skilled in the art, different companies may use different names to refer to the system components.

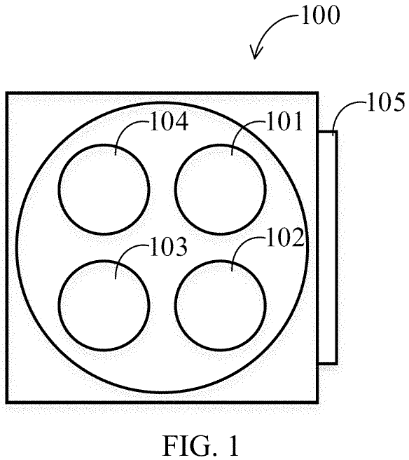

FIG. 1 is a schematic structural diagram of a processing chamber 100 including a plurality of processing stations 101, 102, 103, and 104. Although a particular number of processing stations are shown in FIG. 1, a person skilled in the art will understand that the processing chamber 100 may include fewer or more processing stations.

As shown in FIG. 1, the processing chamber 100 includes a valve 105. The processing chamber 100 may be connected to an adjacent chamber (for example, a transfer chamber) through the valve 105. When the valve 105 is opened, a mechanical arm in the adjacent chamber may transfer a to-be-processed wafer into the processing chamber 100 through the valve 105, or transfer a processed wafer out of the processing chamber 100 through the valve 105. In an exemplary arrangement shown in FIG. 1, the mechanical arm in the adjacent chamber can simultaneously transfer two wafers into the processing chamber 100 or out of the processing chamber 100. In another embodiment, the mechanical arm in the adjacent chamber can transfer only one wafer once or transfer more wafers simultaneously.

A wafer transfer method in which a rotation mechanism in the processing chamber is used is described below with reference to the processing chamber 100 shown in FIG. 1. Similar methods can be implemented for processing chambers with other arrangements.

When the valve 105 is opened, the mechanical arm in the adjacent chamber simultaneously transfers two wafers to the processing stations 101 and 102 relatively closer to the valve 105, respectively. Then, the wafers in the processing stations 101 and 102 are transferred to positions relatively farther from the valve of the processing chamber by using a rotation mechanism. For example, the processing stations 101, 102, 103, and 104 can be rotated around the center of the processing chamber, so that the processing stations 101 and 102 together with the wafers therein are rotated to positions in which the processing stations 103 and 104 previously are; or, positions of the processing stations 101, 102, 103, and 104 remain unchanged, and the wafers in the processing stations 101 and 102 are moved into the processing stations 103 and 104 by using a wafer rotation apparatus in the processing chamber 100. After the rotation, there is no wafer in two processing stations relatively closer to the valve 105 (for example, in a case that the processing stations are rotated, the two processing stations are the processing stations 103 and 104; and in a case that the wafers are rotated, the two processing stations are still the processing stations 101 and 102). Then, the mechanical arm in the adjacent chamber can simultaneously transfer another two wafers to the two processing stations relatively closer to the valve 105, respectively. Between the two transfers of the mechanical arm and depending on a specific process step, the valve 105 can be kept opened all the time or closed first and then opened. After wafers are placed into all of the processing stations 101, 102, 103, and 104, the valve 105 can be closed to perform semiconductor treatment processes, such as deposition, etching, and cleaning, on the wafers in the processing stations 101, 102, 103, and 104. After treatment processes of the wafers are completed, a similar rotation mechanism is also used when the mechanical arm in the adjacent chamber moves the wafers out of the processing chamber 100.

Implementation of the foregoing transfer method needs to dispose a rotation mechanism (for example, causing the processing station or the wafer to rotate) in the processing chamber 100. As a result, a device structure and operating procedures are relatively complex, and the wafer may be damaged or contaminated during the rotation.

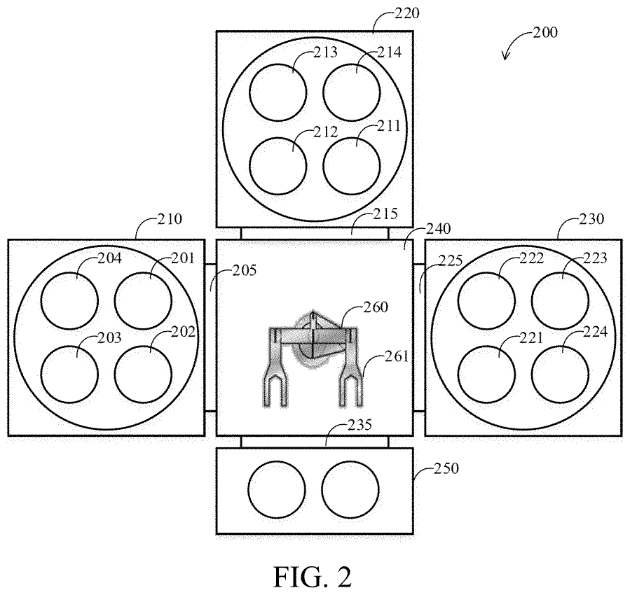

FIG. 2 is a schematic structural diagram of a semiconductor processing system 200 according to some embodiments of this application. The semiconductor processing system 200 includes a processing chamber 210, and processing chamber 220, a processing chamber 230, a transfer chamber 240, and a load lock chamber 250. The transfer chamber 240 is connected to the processing chamber 210, the processing chamber 220, the processing chamber 230, and the load lock chamber 250 respectively through valves 205, 215, 225, and 235. Each processing chamber has 4 processing stations. The processing chamber 210 includes processing stations 201, 202, 203, and 204. The processing chamber 220 includes processing stations 211, 212, 213, and 214. The processing chamber 230 includes processing stations 221, 222, 223, and 224. Although a particular number of processing chambers and processing stations are shown in FIG. 2, a person skilled in the art will understand that the semiconductor processing system 200 may include fewer or more processing chambers and/or processing stations. The processing chambers may alternatively include different numbers of processing stations. The treatment processes performed by the processing chambers may be the same or may be different. The processing system 200 may alternatively have a chamber and station arrangement in other forms.

A mechanical arm 260 is mounted in the transfer chamber 240. The mechanical arm 260 includes two finger portion front ends 261, and each finger portion front end can carry one wafer, so that the mechanical arm 260 can carry two wafers simultaneously. In another embodiment, the mechanical arm 260 may include fewer or more finger portion front ends 261. The mechanical arm 260 is stretchable, and the mechanical arm 260 can be extended so that the finger portion front ends 261 enter any processing chamber or the load lock chamber 250. In some embodiments, the mechanical arm 260 may be mounted on a fixed base (that is, the base is not movable). In some other embodiments, the mechanical arm 260 can be mounted on a movable base (for example, the base can be mounted on a slide rail), so that when the wafer needs to be transferred to a chamber or taken out of a chamber, the base of the mechanical arm 260 can be moved to the vicinity of the chamber.

The following describes a wafer transfer method that can avoid rotation in a processing chamber according to an embodiment of this application with reference to the semiconductor processing system 200 shown in FIG. 2. A similar method can be implemented for a chamber and station arrangement in another form. If it is not necessary, specific time points at which the valves 205, 215, 225, and 235 are opened are not described in detail herein. A person skilled in the art can know when a corresponding valve should be opened to allow the finger portion front ends 261 of the mechanical arm 260 to enter a corresponding chamber.

According to some embodiments of this application, wafers can be first provided to the finger portion front ends 261 of the mechanical arm 260. For example, the finger portion front ends 261 of the mechanical arm 260 can take out the wafers from the load lock chamber 250 (that is, the wafers are moved from the load lock chamber 250 to the finger portion front ends 261 of the mechanical arm 260), or take out the wafers from another processing chamber that performs a previous process. Then, the mechanical arm 260 can be extended, so that the finger portion front ends 261 enter the processing chamber 210 to reach the processing stations 203 and 204, and the wafers on the finger portion front ends 261 are placed into the processing stations 203 and 204. Next, the mechanical arm 260 can be contracted to move the finger portion front ends 261 out of the processing chamber 210. The finger portion front ends 261 can take out wafers from the load lock chamber 250 again. The mechanical arm 260 is extended, so that the finger portion front ends 261 enter the processing chamber 210 to reach the processing stations 201 and 202, and the wafers on the finger portion front ends 261 are placed into the processing stations 201 and 202. Since a distance between the processing station 203 or 204 and the valve 205 is greater than a distance between the processing station 201 or 202 and the valve 205, a length of the mechanical arm 260 extended when the wafers are placed at the processing stations 203 and 204 is greater than that of the mechanical arm 260 extended when the wafers are placed at the processing stations 201 and 202.

The wafers can be placed into the processing stations 211, 212, 213, and 214 of the processing chamber 220 and the processing stations 221, 222, 223, and 224 of the processing chamber 230 in the same manner.

After a treatment process of the wafers in the processing chamber 210 is completed, the mechanical arm 260 may move the wafers out of the processing chamber 210 in the following manner.

First, the mechanical arm 260 is extended to move the finger portion front ends 261 to the processing stations 201 and 202, to pick up the wafers in the processing stations 201 and 202 (that is, the wafers in the processing stations 201 and 202 are moved to the finger portion front ends 261). Then, the mechanical arm 260 is contracted to move the finger portion front ends 261 together with the wafers thereon out of the processing chamber 210. Next, the wafers may be removed from the finger portion front ends 261. For example, the wafers are transferred, by using the mechanical arm 260, to the load lock chamber 250 or another processing chamber that performs a next process. Then, the mechanical arm 260 can be extended to move the finger portion front ends 261 to the processing stations 203 and 204, to pick up the wafers in the processing stations 203 and 204. Then the mechanical arm 260 is contracted to move the finger portion front ends 261 together with the wafers thereon out of the processing chamber 210, and then the wafers are removed from the finger portion front ends 261.

The wafers can be moved out of the processing stations 211, 212, 213, and 214 of the processing chamber 220 and the processing stations 221, 222, 223, and 224 of the processing chamber 230 in the same manner.

In the foregoing example, in the process of transferring wafers to the processing chamber, wafers are first placed at the processing stations (for example, the processing stations 203 and 204) relatively farther from the valve of the chamber, and then wafers are placed at the processing stations (for example, the processing stations 201 and 202) relatively closer to the valve of the chamber. In the process of moving wafers out of the processing chamber, wafers in the processing stations (for example, the processing stations 201 and 202) relatively closer to the valve of the chamber are first moved out, and wafers in the processing stations (for example, the processing stations 203 and 204) relatively farther from the valve of the chamber are then moved out. Using such placing and moving out sequences can avoid contamination caused by the finger portion front end 261s or another part of the mechanical arm 260 passing above wafers placed in the processing station. In some other embodiments, a different placing sequence and/or moving out sequence may alternatively be used.

In some embodiments, the load lock chamber 250 may have a double-layer structure. In other words, the load lock chamber 250 may include an upper-layer load lock chamber and a lower-layer load lock chamber. The mechanical arm 260 can be configured to take out a to-be-processed wafer from a first-layer load lock chamber (for example, the lower-layer load lock chamber) to transfer the to-be-processed wafer to the processing chamber for processing, and place a processed wafer taken out from the processing chamber into a second-layer load lock chamber (for example, the upper-layer load lock chamber). In this way, cross-contamination between the to-be-processed wafer and the processed wafer can be avoided.

In some embodiments, the mechanical arm 260 may have a double-layer structure. In other words, the mechanical arm 260 includes an upper-layer mechanical arm and a lower-layer mechanical arm. The upper-layer mechanical arm includes an upper-layer finger portion front end(s), and the lower-layer mechanical arm includes a lower-layer finger portion front end(s). The mechanical arm 260 can be configured to transfer, by using a first-layer finger portion front end (for example, the upper-layer finger portion front end), a to-be-processed wafer to the processing chamber for processing, and take out, by using a second-layer finger portion front end (for example, the lower-layer finger portion front end), a processed wafer from the processing chamber. In this way, cross-contamination between the to-be-processed wafer and the processed wafer can be avoided. In a case that the double-layer load lock chamber is also used, the mechanical arm 260 can be configured to take out, by using the first-layer finger portion front end (for example, the upper-layer finger portion front end), the to-be-processed wafer from the first-layer load lock chamber (for example, the upper-layer load lock chamber) and transfer the to-be-processed wafer to the processing chamber for processing, and take out, by using the second-layer finger portion front end (for example, the lower-layer finger portion front end), the processed wafer from the processing chamber and place the processed wafer into the second-layer load lock chamber (for example, the lower-layer load lock chamber). The layers of finger portion front ends of and the layers of load lock chambers can cooperate in different forms to implement wafer transfer.

In an embodiment in which the mechanical arm 260 has a double-layer structure, the mechanical arm 260 can perform the operations of taking out the processed wafer and placing the to-be-processed wafer during a single opening stage of the valve of the processing chamber. For example, the to-be-processed wafer(s) can be provided to the first-layer finger portion front end(s) (for example, the upper-layer finger portion front end(s)) of the mechanical arm 260, and then the following operations can be performed during a single opening stage of the valve 205: extending the mechanical arm 260 to move the second-layer finger portion front end(s) (for example, the lower-layer finger portion front end(s)) of the mechanical arm 260 to the processing stations 201 and 202, picking up the processed wafer(s) in the processing stations 201 and 202 by using the second-layer finger portion front end(s) of the mechanical arm 260, and contracting the mechanical arm 260 to move the second-layer finger portion front end(s) of the mechanical arm together with the processed wafer(s) out of the processing chamber 210; and then extending the mechanical arm 260 to move the first-layer finger portion front end(s) of the mechanical arm 260 to the processing stations 201 and 202, placing the to-be-processed wafer(s) at the processing stations 201 and 202, and then contracting the mechanical arm 260 to move the first-layer finger portion front end(s) of the mechanical arm out of the processing chamber 260. After the two operations of taking out the processed wafer and placing the to-be-processed wafer are completed, the processed wafer(s) is (are) removed from the second-layer finger portion front end(s) of the mechanical arm 260. In some embodiments, the processing station(s) from which the second-layer finger portion front end(s) of the mechanical arm 260 takes (take) out the processed wafer(s) may be different from the processing station(s) at which the to-be-processed wafer(s) is (are) placed.

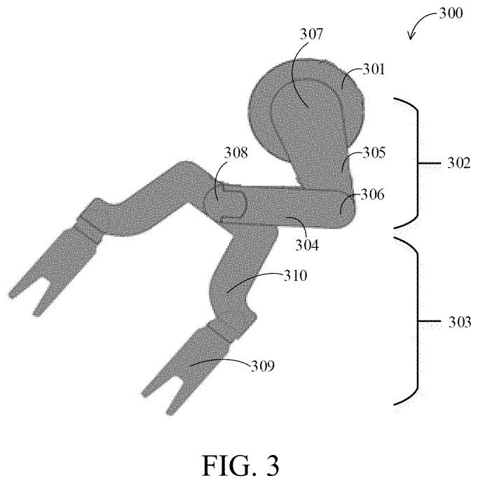

FIG. 3 is a schematic structural diagram of a mechanical arm 300 according to some embodiments of this application. As shown in FIG. 3, the mechanical arm 300 includes a base 301, an extension unit 302, and a finger portion 303. The extension unit 302 is mounted on the base 301 at a supporting point 307, and the finger portion 303 is mounted on the extension unit 302 at a joint 308.

The extension unit 302 includes a small arm portion 304 and a big arm portion 305. One end of the small arm portion 304 is connected to the joint 308, the other end of the small arm portion 304 and one end of the big arm portion 305 are connected at a joint 306, and the other end of the big arm portion 305 is connected to the supporting point 307. The small arm portion 304 can rotate around the joint 308. The small arm portion 304 and the big arm portion 305 can rotate around the joint 306, and the big arm portion 305 can rotate around the supporting point 307. The extension unit 302 can implement extension and contraction of the mechanical arm 300 through the rotation of the small arm portion 304 and the big arm portion 305 around the joints 308 and 306 and the supporting point 307. In some other embodiments, the extension unit of the mechanical arm can be extended and contracted by using an elastically deformable element (for example, a spring mechanism).

The finger portion 303 may include a front end 309 and a rear end 310. The front end 309 may include a structure for carrying a wafer, such as a blade, a paddle, a fork, or a jig. The rear end 310 is connected between the front end 309 and the joint 308. For exemplary purposes only, the front end 309 of the finger portion 303 shown in FIG. 3 can carry two wafers. It should be understood that the front end 309 of the finger portion 303 can alternatively carry only one wafer or more than two wafers.

The front end 309 will come into direct contact with a wafer, and therefore may be made of a material such as ceramic that is not easy to cause particle or impurity contamination when being in contact with the wafer. Other parts of the mechanical arm 300 may be made of metal materials.

In some embodiments, the mechanical arm 300 may be used for implementing the foregoing wafer transfer method described with reference to FIG. 2 that can avoid rotation in a processing chamber. When implementing the method, the mechanical arm needs to be extended long enough to enable the finger portion front end of the mechanical arm to reach a far-end position of the processing chamber (for example, the processing stations 203 and 204 of the processing chamber 210). For example, the length of the extended mechanical arm needs to be not less than 1250 mm. In some applications, the length of the extended mechanical arm needs to reach 1285 mm or 1360 mm. However, extending the mechanical arm 300 to a relatively large length may cause a problem such as trembling in wafer transfer. Therefore, it is necessary to design a stabilization mechanism to enhance the stability of the mechanical arm.

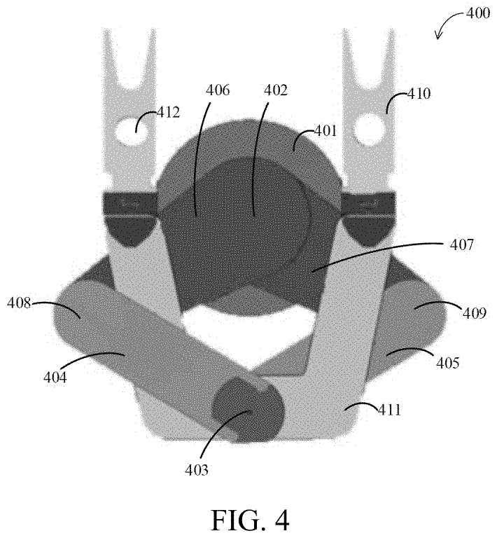

FIG. 4 is a schematic structural diagram of a mechanical arm 400 according to some embodiments of this application. The mechanical arm 400 may have enhanced stability.

As shown in FIG. 4, the mechanical arm 400 includes a base 401, an extension unit, and a finger portion. The extension unit is mounted on the base 401 at a supporting point 402, and the finger portion is mounted on the extension unit at a joint 403.

The extension unit includes a first small arm portion 404, a second small arm portion 405, a first big arm portion 406, and a second big arm portion 407. A first end of the first small arm portion 404 and a first end of the second small arm portion 405 are connected at the joint 403. A second end of the first small arm portion 404 and a first end of the first big arm portion 406 are connected at a joint 408. A second end of the second small arm portion 405 and a first end of the second big arm portion 407 are connected at a joint 409. A second end of the first big arm portion 406 and a second end of the second big arm portion 407 are jointly connected to the supporting point 402. Compared with the mechanical arm 300, an additional group of a big arm portion and a small arm portion is added to the extension unit of the mechanical arm 400, so that the finger portion can be supported more stably. A reinforcing rib may be further added below one or more of the first small arm portion 404, the second small arm portion 405, the first big arm portion 406, and the second big arm portion 407.

The first small arm portion 404 and the second small arm portion 405 can rotate around the joint 403. The first small arm portion 404 and the first big arm portion 406 can rotate around the joint 408. The second small arm portion 405 and the second big arm portion 407 can rotate around the joint 409. The first big arm portion 406 and the second big arm portion 407 can rotate around the supporting point 402. The extension unit can implement extension and contraction of the mechanical arm 400 through the rotation of the first small arm portion 404, the second small arm portion 405, the first big arm portion 406, and the second big arm portion 407 around the joints 403, 408, and 409 and the supporting point 402.

In some embodiments, the first big arm portion 406 and the second big arm portion 407 are thicker than the first small arm portion 404 and the second small arm portion 405. In some embodiments, the second end of the first big arm portion 406 and the second end of the second big arm portion 407 are thicker than the first end of the first big arm portion 406 and the first end of the second big arm portion 407. In some embodiments, the second end of the first small arm portion 404 and the second end of the second small arm portion 405 are thicker than the first end of the first small arm portion 404 and the first end of the second small arm portion 405. In other words, along a direction from the supporting point 402 to the finger portion, the arm portions can gradually become thinner, so that the trembling of the mechanical arm 400 during wafer transfer can be alleviated.

The finger portion includes a front end 410 and a rear end 411. The front end 410 may include a structure for carrying a wafer, such as a blade, a paddle, a fork, or a jig. The rear end 411 is connected between the front end 410 and the joint 403. For exemplary purposes only, the front end 410 of the finger portion shown in FIG. 4 can carry two wafers. It should be understood that the front end 410 of the finger portion can alternatively carry only one wafer or more than two wafers.

In some embodiments, the front end 410 may include a hollow part, for example, a hole 412 shown in FIG. 4, to reduce the weight of the front end 410.

In some embodiments, to carry the wafer more stably, the front end 410 may include a plurality of contact points, a plurality of contact lines, or a plurality of contact bevels for supporting the wafer from a side of the wafer. In some embodiments, the number of the contact points is not less than 4. In some embodiments, the front end 410 may include a suction cup for sucking the wafer from the back of the wafer, such as an electrostatic suction cup or a vacuum suction cup.

The front end 410 will come into direct contact with a wafer, and therefore may be made of a material such as ceramic that is not easy to cause particle or impurity contamination when being in contact with the wafer. Other parts of the mechanical arm 400 may be made of metal materials.

In some embodiments, the mechanical arm 400 may have a double-layer structure. That is, in addition to the extension unit and the finger portion described above, the mechanical arm 400 may further include: a second-layer extension unit mounted on the base 401, and a second-layer finger portion mounted on the second-layer extension unit. The second-layer extension unit and the second-layer finger portion may have a structure similar to that of the extension unit and the finger portion described above. In some embodiments, the two layers of extension units are both mounted at the supporting point 402. In some embodiments, the two layers of extension units can extend independently of each other, so that the two layers of finger portions can be respectively used to take out a processed wafer from a processing chamber and place a to-be-processed wafer into the processing chamber, to avoid cross-contamination between the to-be-processed wafer and the processed wafer.

This application provides a wafer transfer method that can avoid rotation in a processing chamber in an aspect, and in another aspect, provides a mechanical arm having enhanced stability, which can more effectively implement the foregoing method.

The description in the specification is provided to enable a person skilled in the art to perform or use the present disclosure. Various modifications to the present disclosure are obvious to a person skilled in the art, and the general principles defined in the specification can be applied to other variations without departing from the spirit or scope of the present disclosure. Therefore, the present disclosure is not limited to the examples and designs described in the specification, but is given the widest scope consistent with the principles and novel features disclosed in the specification.

What is claimed is:

1. A wafer transfer method, comprising:
providing a first wafer to a finger portion front end of a mechanical arm;
extending the mechanical arm to a first length to move the finger portion front end of the mechanical arm to a first processing position in a first processing chamber;
placing the first wafer at the first processing position;
contracting the mechanical arm to move the finger portion front end of the mechanical arm out of the first processing chamber;
providing a second wafer to the finger portion front end of the mechanical arm;
extending the mechanical arm to a second length to move the finger portion front end of the mechanical arm to a second processing position in the first processing chamber, wherein the second length is different from the first length; and
placing the second wafer at the second processing position.

2. The method according to claim 1, comprising:
moving a base of the mechanical arm to the vicinity of the first processing chamber before extending the mechanical arm to the first length.

3. The method according to claim 1, further comprising:
providing a third wafer to the finger portion front end of the mechanical arm;
extending the mechanical arm to a third length to move the finger portion front end of the mechanical arm to a third processing position in a second processing chamber; and
placing the third wafer at the third processing position.

4. The method according to claim 3, comprising:
moving a base of the mechanical arm to the vicinity of the second processing chamber before extending the mechanical arm to the third length.

5. The method according to claim 1, further comprising:
moving the first wafer and the second wafer out of the first processing chamber after treatment processes of the first wafer and the second wafer are completed, wherein
moving the first wafer out of the first processing chamber comprises:
extending the mechanical arm to the first length to move the finger portion front end of the mechanical arm to the first processing position;
moving the first wafer from the first processing position to the finger portion front end of the mechanical arm;
contracting the mechanical arm to move the first wafer out of the first processing chamber; and
removing the first wafer from the finger portion front end of the mechanical arm; and
moving the second wafer out of the first processing chamber comprises:
extending the mechanical arm to the second length to move the finger portion front end of the mechanical arm to the second processing position;
moving the second wafer from the second processing position to the finger portion front end of the mechanical arm;
contracting the mechanical arm to move the second wafer out of the first processing chamber; and
removing the second wafer from the finger portion front end of the mechanical arm.

6. The method according to claim 5, wherein the first wafer is placed at the first processing position before the second wafer is placed at the second processing position, and the second wafer is moved out of the first processing chamber before the first wafer is moved out of the first processing chamber.

7. The method according to claim 5, wherein providing the first wafer to the finger portion front end of the mechanical arm comprises moving the first wafer from a first-layer load lock chamber to the finger portion front end of the mechanical arm, and removing the first wafer from the finger portion front end of the mechanical arm comprises moving the first wafer from the finger portion front end of the mechanical arm to a second-layer load lock chamber.

8. The method according to claim 1, wherein the finger portion front end of the mechanical arm is a first-layer finger portion front end of the mechanical arm, and the method further comprises:
extending, after a treatment process of the first wafer is completed, the mechanical arm to move a second-layer finger portion front end of the mechanical arm to the first processing position;
moving the first wafer from the first processing position to the second-layer finger portion front end of the mechanical arm;
contracting the mechanical arm to move the first wafer out of the first processing chamber; and
removing the first wafer from the second-layer finger portion front end of the mechanical arm.

9. The method according to claim 8, wherein providing the first wafer to the finger portion front end of the mechanical arm comprises moving the first wafer from a first-layer load lock chamber to the first-layer finger portion front end of the mechanical arm, and removing the first wafer from the second-layer finger portion front end of the mechanical arm comprises moving the first wafer from the second-layer finger portion front end of the mechanical arm to a second-layer load lock chamber.

10. The method according to claim 8, comprising: after contracting the mechanical arm to move the first wafer out of the first processing chamber and before removing the first wafer from the second-layer finger portion front end of the mechanical arm, extending the mechanical arm to move the first-layer finger portion front end of the mechanical arm to the first processing position, and placing a third wafer on the first-layer finger portion front end at the first processing position.

11. A wafer transfer method, comprising:
providing a first wafer to a first-layer finger portion front end of a mechanical arm; and
performing the following operations during a single opening stage of a valve of a first processing chamber:
extending the mechanical arm to move a second-layer finger portion front end of the mechanical arm to a first processing position in the first processing chamber;
moving a second wafer in the first processing position to the second-layer finger portion front end of the mechanical arm;
contracting the mechanical arm to move the second wafer out of the first processing chamber;
extending the mechanical arm to move the first-layer finger portion front end of the mechanical arm to a second processing position in the first processing chamber;
placing the first wafer at the second processing position; and
contracting the mechanical arm to move the first-layer finger portion front end of the mechanical arm out of the first processing chamber.

12. The method according to claim 11, wherein the first processing position and the second processing position are the same processing position.

13. A mechanical arm, comprising:
a first-layer extension unit mounted on a base, comprising a first small arm portion, a second small arm portion, a first big arm portion, and a second big arm portion, wherein a first end of the first small arm portion and a first end of the second small arm portion are connected at a first joint, a second end of the first small arm portion and a first end of the first big arm portion are connected at a second joint, a second end of the second small arm portion and a first end of the second big arm portion are connected at a third joint, and a second end of the first big arm portion and a second end of the second big arm portion are jointly connected to a supporting point on the base; and
a first-layer finger portion, mounted on the first joint of the first-layer extension unit.

14. The mechanical arm according to claim 13, wherein the first big arm portion and the second big arm portion are thicker than the first small arm portion and the second small arm portion.

15. The mechanical arm according to claim 13, wherein the second end of the first big arm portion and the second end of the second big arm portion are thicker than the first end of the first big arm portion and the first end of the second big arm portion.

16. The mechanical arm according to claim 13, wherein the second end of the first small arm portion and the second end of the second small arm portion are thicker than the first end of the first small arm portion and the first end of the second small arm portion.

17. The mechanical arm according to claim 13, wherein the first small arm portion and the second small arm portion are operable to rotate around the first joint, the first small arm portion and the first big arm portion are operable to rotate around the second joint, the second small arm portion and the second big arm portion are operable to rotate around the third joint, and the first big arm portion and the second big arm portion are operable to rotate around the supporting point.

18. The mechanical arm according to claim 13, wherein the first-layer finger portion comprises:
a front end for carrying a wafer; and
a rear end, connected between the front end and the first joint.

19. The mechanical arm according to claim 18, wherein the front end comprises a hollow part.

20. The mechanical arm according to claim 18, wherein the front end comprises a plurality of contact points, a plurality of contact lines, or a plurality of contact bevels for supporting the wafer from a side of the wafer.

21. The mechanical arm according to claim 18, wherein the front end comprises a suction cup for sucking the wafer from the back of the wafer.

22. The mechanical arm according to claim 21, wherein the suction cup comprises an electrostatic suction cup or a vacuum suction cup.

23. The mechanical arm according to claim 13, further comprising:
a second-layer extension unit mounted on the base; and a second-layer finger portion mounted on the second-layer extension unit.

24. The mechanical arm according to claim 23, wherein the first-layer extension unit and the second-layer extension unit are operable to extend independently of each other.
